(19) United States
(12) Patent Application Publication
(10) Pub. No.: US 2012/0115312 A1
(43) Pub. Date: May 10, 2012

(54) THIN FILMS FOR PHOTOVOLTAIC CELLS

(75) Inventors: Rakesh Agrawal, West Lafayette, IN (US); Hugh W. Hillhouse, Seattle, WA (US); Qijie Guo, West Lafayette, IN (US); Mahaprasad Kar, Bartlesville, OK (US)

(73) Assignee: PURDUE RESEARCH FOUNDATION, West Lafayette, IN (US)

(21) Appl. No.: 13/321,834

(22) PCT Filed: May 26, 2010
(86) PCT No.: PCT/US2010/036259

§ 371 Date: Jan. 20, 2012

Related U.S. Application Data
(60) Provisional application No. 61/181,154, filed on May 26, 2009.
(60) Provisional application No. 61/181,159, filed on May 26, 2009.

(51) Int. Cl. H01L 21/20

(52) U.S. Cl. 438/478; 257/E21.09

(57) ABSTRACT

In one aspect, a method for forming CIGSSe-based thin films includes depositing at least two layers of particles on a substrate. At least one layer includes a CIGSSe particle having a chemical composition denoted by Cu(InI-xGax)(S1-ySey)2 where 0≦x ≦1 and 0≦y≦1. The particle layers are annealed individually or in combination to form a CIGSSe thin film having a composition profile along the depth of the film In addition, one or more of the particle layers may be also deposited on a pre-existing absorber and annealed to form a film having a composition profile along the depth of the film After depositing thin film precursor layers containing CIGSSe nanoparticles (and/or any other particles) on a suitable substrate in accordance with a desired concentration profile, a subsequent treatment under an Se and/or S containing atmosphere at elevated temperature may be used to convert the precursor layers into a CIGSSe absorber film In a further aspect, a method for forming multinary metal chalcogenide semiconductor layers directly on a substrate from a solution of precursors, includes depositing a plurality of metal chalcogenide particles onto a substrate to form a precursor film A species containing a metal, chalcogen, or combination thereof is dissolved in a solution containing one or more solvents to form a liquid chalcogen medium. The precursor film is contacted with the liquid chalcogen medium at a temperature of at least 50 C to form a multinary metal chalcogenide thin film

### DETAILED DESCRIPTION

This application claims the benefit of priority under 35 U.S.C. §119(e) to U.S. Provisional Patent Application No. 61/181,154, filed May 26, 2009, and U.S. Provisional Patent Application No. 61/181,159, filed May 26, 2009, both of which are incorporated by reference in their entirety.

### FIELD OF THE INVENTION

The present disclosure relates to thin films for photovoltaic cells, including the fabrication and control of a composition profile along the depth of Group I-III-VI2 absorber films, including Cu(In₁₋ₓGaₓ(S_{1-y} Se_{y},)₂ absorber films, and chemical liquid deposition and solution phase chalcogenization for formation of multinary metal chalcogenide thin films.

### BACKGROUND

Solar cells are photovoltaic devices that convert the energy in the solar photons directly into electrical energy. The most common semiconductor used in solar cells is silicon, which is either in the form of monocrystalline or polycrystalline wafers. However, the cost of electricity generated using silicon-based solar cells is much higher than that from more traditional methods. One way of reducing the cost of generating electricity from solar cells is to develop thin film growth techniques that can deposit device-quality absorber materials on large area substrates using low-cost methods.

Due to their unique structural and electrical properties, semiconductor materials comprised of copper (Cu), indium (In), gallium (Ga), sulfur (S), and/or selenium (Se), including CuInS₂, CuInSe₂, CuGaS₂, CuGaSe₂, Cu(In₁₋ₓGaₓ)S₂, Cu(In₁₋ₓGaₓ)Se₂, and Cu(In₁₋₁Gaₓ)(S_{1-y}Se_{y})₂, where 0≦x≦1 and 0≦y≦1 (denoted herein as CIGSSe thin films), represent some of the most promising candidate materials for producing thin films for low cost photovoltaic applications (1-3). The highest quality CIGS or CIGSSe thin films have been traditionally fabricated using vacuum co-evaporation (4). However, their high production costs have hampered large scale fabrication efforts. Recently, solar cells with CIGSSe absorber layers fabricated by deposition of alloys of copper, indium, gallium, selenium, or sulfur have been developed using alternative approaches (5-11).

Among the various alternatives, printing or coating technologies utilizing nanoparticle inks present a promising, low-cost, high throughput alternative for solar cell production as compared to traditional vacuum based deposition methods. One such method involves developing a nanoparticle ink of metals (Cu, In, Ga) or metal-oxides followed by spray-coating into thin films and then selenization (550° C.) with the selenium-containing species present in the vapor phase, to obtain the CIGS layer (12,13). However, films produced by this technique show spatial non-uniformities in composition and also lead to expansion (cracking) during the selenization step (14). Another commercially used method involves the sputtering of metals (Cu, In, Ga) onto a substrate, followed by selenization of the metal layers with selenium-containing species present in the vapor phase. Formation of binary selenides, Ga collection near the back contact and delamination of films during selenization present issues that are yet to be resolved (15). Other methods have low material utilization or use toxic gases for selenization, like hydrogen selenide (TWA-TLV: 50 ppb), or result in poorly-crystalline films leading to low conversion efficiencies (16).

Syntheses of semiconductor nanocrystals have been developed for more than 3 decades, but have only been recently reported for use in photovoltaic devices (17,18). Gur et al. (19) demonstrated fabrication of CdTe/CdSe based solar cells in which the individual films were spin-coated from nanorods prepared by colloidal routes. The devices show an order of magnitude improvement in the efficiency (0.1% to 3%) upon exposing the nanocrystalline films to a solution of CdCl₂ in methanol at room temperature after which they were removed from the solution and annealed at 400° C. in air. Sager et al described a method of solution-based deposition of coated nanoparticles comprised of Cu, In, Ga and Se over desired substrates and subsequent thermal annealing to form the corresponding absorber film (20). More recently, Guo et al. described a solution-chemistry based process for synthesizing stoichiometric, crystalline and chalcopyrite-structured CuInSe₂ and CuInGaSe₂ nanocrystals, and using such nanoparticles as an alternative method for low cost solar cells (21,22).

The optical and electrical properties of the CIGSSe absorbers depend on their composition. Thus, one of the major challenges to all of the deposition techniques reported is the ability to control and maintain the composition at the molecular level. Typically, composition control along the depth of the CIGSSe absorber film has been done by vacuum co-evaporation through precise control of In and Ga fluxes during deposition. However, composition non-homogeneity has been reported with vacuum co-evaporated CIGSSe absorber films resulting in non-uniformity in device performance, especially open circuit voltage. Composition non-uniformity is also created due to the high mobility of the Cu, In, and Ga ions at the high temperatures (−600° C.) utilized during the deposition process, whereby Ga segregation near the back of the film is typically observed (23). Furthermore, vacuum co-evaporation is not a suitable method for large area and high throughput production of the absorber.

Others have reported surface modifications to a pre-existing dense CIGSSe absorber with H₂S or H₂Se in order to change its composition near the junction (24,25). However, such approaches typically require highly toxic gases under high temperature conditions, thereby limiting their applicability for large scale production. Moreover, the chalcogen exchange reaction is not well controlled and typically limited by the experimental conditions. Furthermore, the surface modification in such methods is limited to gaseous chalcogen species, rather than adjusting the metal species (Cu, In, Ga) or their ratios in relation to one another. Thus, alternative methods for surface composition modifications to a pre-existing dense or non-dense CIGSSe absorber are desired, especially those sufficient for generating a composition depth profile in the newly formed absorber film or in relation to a pre-existing absorber layer.

### SUMMARY

In one aspect, the present invention provides compositions and methods for forming CIGSSe-based thin films having a composition profile along the depth of the film. The method for forming a CIGSSe thin film includes depositing at least two layers of particles on a substrate. The first layer of particles includes a plurality of a CIGSSe particle having a chemical composition denoted by Cu(In₁₋ₓ₁Gaₓ₁)(S_{1-y1}Se_{y1})₂ where 0≦x₁≦1 and 0≦y₁≦1. The second layer of particles includes a plurality of a CIGSSe particle having a chemical composition denoted by Cu(In₁₋ₓ₂Gaₓ₂)(S_{1-y2}Se_{y2})₂ where 0≦x₂≦1 and 0≦y₂≦1; a plurality of a CIGSSe family particle containing at least one element from Cu, In, Ga, S, and Se; or both. The particle layers are annealed individually or in combination to form a CIGSSe thin film having a composition profile along the depth of the film. The annealing step may be carried out in an S and/or Se containing environment at elevated temperatures.

A third portion of particles includes a plurality of a third particle that may be incorporated into any one of the first and second layers in the form of a mixture or as an additional layer prior to annealing. The third particle may be another CIGSSe particle, herein denoted by Cu(In₁₋ₓ₃Gaₓ₃)(S_{1-y3}Se_{y3})₂ where 0≦x₃≦1 and 0≦y₃≦1, or it may be a CIGSSe family particle containing at least one of Cu, In, Ga, S, and Se. Particle compositions, including particle mixtures, are preferably deposited on the substrate or on another layer using one or more particle ink compositions.

After depositing thin film precursor layers containing CIGSSe nanoparticles (and/or any other particles) on a suitable substrate in accordance with a desired concentration profile, a subsequent treatment under an Se and/or S containing atmosphere at elevated temperature may be used to convert the precursor layers into a CIGSSe absorber film.

In another embodiment, single- or multilayer coatings containing CIGSSe nanoparticles are deposited on pre-existing CIGSSe absorbers for surface composition modification of the pre-existing CIGSSe absorber film. In one embodiment, a substrate having an absorber formed thereon is provided, whereby a layer of particles is deposited thereon to form a composite precursor film, the layer of particles containing a plurality of a CIGSSe particle having a chemical composition denoted by Cu(In₁₋ₓ₁Gaₓ₁)(S_{1-y1}Se_{y1})₂ where 0≦x₁≦1 and 0≦y₁≦1. Upon annealing, the composite precursor film forms a CIGSSe thin film having a composition profile along the depth of the film. In another embodiment, a multilayer coating or precursor film as described above is formed on the pre-existing absorber, whereby the subsequent step follow those outlined above.

In a further aspect, a method for forming multinary metal chalcogenide semiconductor layers directly on a substrate from a solution of precursors, includes depositing a plurality of metal chalcogenide particles onto a substrate to form a precursor film. A species containing a metal, chalcogen, or combination thereof is dissolved in a solution containing one or more solvents to form a liquid chalcogen medium. The precursor film is contacted with the liquid chalcogen medium at a temperature of at least 50° C. to form a multinary metal chalcogenide thin film. Thus, when the precursor film on the substrate is brought in contact with either a chalcogen and/or a metal-containing species dissolved in a liquid phase medium, a thin film of a multinary metal chalcogenide compound may form from the metals present in the precursor film and the liquid phase medium.

Metal chalcogenide particles for deposition on the precursor film include one or more elements from each of Groups IB, IIIA, and VIA of the Periodic Table (CAS Version, CRC Handbook Version, CRC Handbook of Chemistry and Physics). Elements from Groups IB, IIIA, and VIA may be present in the deposited particles as elements, binary compounds, ternary compounds, quaternary compound, or combinations thereof. The precursor film may include, for example, (1) Cu and/or In and/or Ga as metals or alloys; (2) binary metal compounds, including binary metal compounds of Cu, In, Ga such as Cu_{z}Se, Cu_{z}S, Cu_{z}O (where 1≦z≦2), InₜSe, InₜS, InₜO, GaₜSe, GaₜS and GaₜO (where 0.5≦t≦1) etc.; (3) ternary compounds of Cu and/or In and/or Ga such as CuInS₂, CuGaS₂, CuInSe₂ etc.; or (4) quaternary compounds of Cu, In and Ga such as CuIn₁₋ₓGaₓ(S_{y}Se_{1-y})₂ where, 0≦x≦1 and 0≦y≦1.

The liquid chalcogen medium may include an elemental chalcogen (such as S, Se), a chalcogen complex (such as trioctylphosphine selenium complex), a non-metal chalcogen compound (such as sodium selenide, sodium sulfide, selenourea, thiourea, H₂S and H₂Se in solution), a metal chalcogen compound (such as FeS₂, NiS, Bi₂S₃, PbS, CdS, or Cu₂S), a metal chalcogen salt, or combination thereof

The disclosure further describes methods for fabricating photovoltaic cells with the above described thin films.

### BRIEF DESCRIPTION OF THE DRAWINGS

FIG. 1 depicts examples of the different band gap profiles achievable by controlling the concentration profile along the depth of the CIGSSe absorber film.

FIG. 2 depicts sequence schematic diagrams illustrating formation of a CIGSSe absorber by thermal annealing of thin film layers containing CIGSSe nanoparticles under Se and/or S atmosphere according to an embodiment of the present invention.

FIG. 3 depicts a powder X-ray diffraction (PXRD) analysis of as-synthesized Cu(In₁₋ₓGaₓ)S₂ nanoparticles with varied x coated on molybdenum substrates.

FIG. 4 depicts FE-SEM image of the CIGSSe nanoparticle layer coated on molybdenum substrate showing a dense packing of the constituent nanoparticles.

FIG. 5 depicts a PXRD analysis of Cu(In₁₋ₓGaₓ)S₂ thin films with varied x coated on molybdenum substrate after annealing under Se vapor at 500° C. for 20 minutes.

FIG. 6 depicts FE-SEM image of a CIGSSe absorber after annealing under Se vapor at 500° C. for 20 minutes showing the large and densely packed grains after selenization.

FIG. 7 depicts current vs. voltage characteristic of photovoltaic devices fabricated using various CIGSSe nanoparticles coatings containing a) CuInS₂ nanoparticles solely, b) Cu(InGa)S₂ nanoparticles solely, and c) CuInS₂/Cu(In,Ga)S₂ bi-layer as described in the embodiment of the present invention.

FIG. 8 depicts current vs. voltage characteristic of photovoltaic devices fabricated using CIGSSe absorbers made a) KCN etching post Se vapor annealing, and b) KCN etching pre and post Se vapor annealing.

FIG. 9 depicts a schematic of an experimental apparatus for solution phase synthesis of nanocrystals according to the embodiments described in Examples 1 and 2.

FIG. 10 depicts FE-SEM images of (a) the top view of a precursor film of Cu_{1.75}Se nanocrystals on a Mo substrate; (b) a cross-sectional side view along the thickness of a CuInSe₂ thin film as described in Example 1.

FIG. 11 depicts a PXRD analysis of the CuInSe₂ thin film described in Example 1.

FIG. 12 depicts the AM 15 illuminated current vs. voltage characteristics of a solar cell fabricated according to Example 1.

### DEFINITIONS

In order to provide a clear and consistent understanding of the specification and claims, the following definitions are provided.

As used herein, the term “nanoparticle” means a discrete entity, particle or crystal with at least one dimension having a size between about 1 nm to about 1000 nm, between about 1 nm to 100 nm, between about 1 nm to about 25 nm, or between about 1 nm and about 15 nm.

As used herein, the term CIGSSe nanoparticle refers to a nanoparticle containing an alloy of Cu, In, Ga, S and Se in accordance with a chemical composition denoted by Cu(In₁₋ₓGaₓ)(S_{1-y}Se_{y})₂, where 0≦x≦1 and 0≦y≦1.

As used herein, the or CIGSSe precursor film refers to a precursor film having two or more layers comprising CIGSSe nanoparticles prior to annealing in an S and/or Se environment.

As used herein, the term “CIGSSe absorber” refers to an absorber film comprising various alloys of Cu, In, Ga, S and Se in accordance with a chemical composition denoted by Cu(In₁₋ₓGaₓ)(S_{1-y}Se_{y})₂, where 0≦x≦1 and 0≦y≦1. Exemplary GIGSSe alloys include CuInS₂, CuInSe₂, CuGaS₂, CuGaSe₂, Cu(In₁₋ₓGaₓ)S₂, Cu(In₁₋ₓGaₓ)Se₂, and Cu(In₁₋ₓGaₓ)(S_{1-y}Se_{y})₂, where 0≦x≦1 and 0≦y≦1.

As used herein, the term “CIGSSe family” refers to a particle or thin film precursor layer formed therefrom that contains one or more elements from Cu, In, Ga, S, and Se.

As used herein, the term “layer” refers to the deposition of particles, such as from an ink solution, for example, whereby the particles are deposited so as to fully or at least partly cover another layer or substrate.

As used herein, the term “stoichiometric” may be applied to a solid film of a material, such as a layered superlattice material or thin film; or a precursor for forming a material, such as a thin film coating, thin film coating layer, or a nanoparticle composition or mixture as contained in a nanoparticle ink solution, for example. When applied to a solid thin film, “stoichiometric” refers to a formula showing the actual relative amounts of each element in a final solid thin film. When applied to a precursor, it indicates the molar proportion of metals in the precursor. A stoichiometric formula may be balanced or unbalanced. A “balanced” stoichiometric formula is one in which there is just enough of each element to form a complete crystal structure of the material with all sites of the crystal lattice occupied, though in actual practice there may typically be some defects in the crystal at room temperature. An unbalanced “stoichiometric” formula is one in which the molar proportions of exhibit an excess and/or deficiency in one element relative to another element.

As used herein, the term “precursor” may be used with reference to an organic or inorganic compound or solution utilized as a reactant in nanoparticle synthesis, or with reference to thin film prior to annealing in an S and/or Se environment.

As used herein, the term “conductive substrate” refers to either substrate, including a conductive layer thereon, or a substrate made of a conductive material.

### Composition Depth Profiling

A major challenge in CIGSSe absorber based thin film solar cell technology is the ability to precisely control the composition profile along the depth of the film. It is believed that the ability to profile the composition or band gap along the depth of the film would significantly impact the photovoltaic performance of the resulting CIGSSe film. It is well established that the band gap energy of CIGSSe absorbers in thin films can be controlled by varying the corresponding Ga/(Ga+In) and S/(S+Se) ratios. For example, the band gap energy of CIGSSe thin films widens with incorporation of Ga content due to up-shift of the conduction band edge. It is also believed that the valence band edge of CIGSSe can also be down-shifted by increasing the amount of S relative to Se. The band gap energy of CIGSSe thin films depend on their composition and can range anywhere between about 1.02 eV for CuInSe₂ to about 2.41 eV for CuGaS₂. Thus, variation in the composition depth profile can lead to variation in the band gap across the depth or thickness of the film. Therefore, the present invention is predicated on providing a composition depth profiling methodology allowing for a desired band gap profile on a desired substrate.

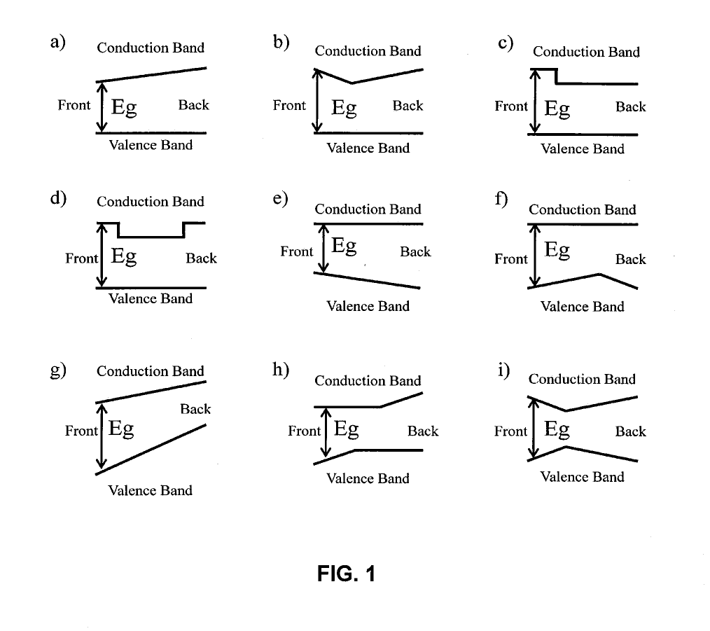

FIG. 1 illustrates various hypothetical band gap profiles. As shown in FIG. 1a, a graded band gap profile along the depth of film creates a gradient in the conduction band which creates an electric field that can facilitate the transport of the excited carriers through the absorber. In some cases, a higher band gap profile is desired at the front of the CIGSSe absorber for higher open circuit voltage. However, significant levels of photons with energies lower than the band gap energies at the front of the CIGSSe absorber may not be absorbed, ultimately leading to lower photocurrent collected and lower efficiency. Thus, it is desirable to have a lower band gap energy in the CIGSSe absorber at the bottom to absorb the transmitted photons while maintaining the advantage of high open circuit voltage due to the higher band gap profile at the front, analogous to the benefits of a multi-junction solar cell but in a single junction device as shown in FIG. 1c. Other band gap profiles of interest are depicted in (FIGS. 1b and 1d-1i).

In one aspect, the present disclosure provides an approach to control the composition depth or band gap profiles in CIGSSe absorbers. Composition depth profiles in CIGSSe absorbers may be beneficially achieved by utilizing CIGSSe nanoparticles with varied ratios of x and/or y. By utilizing CIGSSe nanoparticles to provide different, controllable ratios of x and/or y in multilayer coatings of CIGSSe nanoparticles, distinct band gap profiles may be obtained, including those reflected in the various concentration depth profiles shown in FIG. 1.

### Formation of CIGSSe-based Absorber Films

In one embodiment, the present disclosure provides a method for forming a CIGSSe-based thin film. In accordance with this method, at least two layers of particles are deposited on a substrate. The first layer contains a plurality of a CIGSSe particle having a chemical composition denoted by Cu(In₁₋ₓ₁Gaₓ₁)(S_{1-y1}Se_{y1})₂ where 0≦x₁≦1 and 0≦y₁≦1. The second layer contains a plurality of a CIGSSe particle having a chemical composition denoted by Cu(In₁₋ₓ₂Gaₓ₂)(S_{1-y2}Se_{y2})₂ where 0≦x₂≦1 and 0≦y₂≦1. One or both of the first and second layers of particles are annealed individually or in combination to form a CIGSSe thin film or absorber film having a composition profile along the depth of the film. It should be noted that either one of the Cu(In₁₋ₓ₁Gaₓ₁)(S_{1-y1}Se_{y1)}₂ particles or the Cu(In₁₋ₓ₂Gaₓ₂)(S_{1-y2}Se_{y2})₂ may be directly deposited on the substrate prior to deposition of the second layer by the other set of particles.

The composition depth profile of a CIGSSe nanoparticle based absorber film will depend on the desired composition, which can be engineered based on the composition of CIGSSe nanoparticles used in their formation. CIGSSe nanoparticle based precursor coatings or absorber films made with CIGSSe nanoparticles may be stoichiometric, Cu-rich (or excess), Cu-deficient, chalcogen-rich, chalcogen-deficient, In+Ga-rich, or In+Ga-deficient. Likewise, the composition of the CIGSSe nanoparticles may be stoichiometric, Cu-rich (or excess), Cu-deficient, chalcogen-rich, chalcogen-deficient, In+Ga-rich, or In+Ga-deficient.

In accordance with the objective of providing varied band gap or composition depth profiles, x₁, y₁, x₂, and y₂ may be varied so as to promote variation of x and/or y along the depth of a thin film. Accordingly, the values of x₁, y₁, x₂, and y₂ may be varied in a number of different ways. In one embodiment, x₁=x₂. In another embodiment y₁=y₂. In yet another embodiment, at least one of x₁ and x₂ is equal to 0. In a further embodiment, at least one of y₁ and y₂ is equal to 0. In a preferred embodiment, at least one of y₁ and y₂ is less than 1. In yet another embodiment, 0<y₁<1 or 0<y₂<1.

In a further aspect, a portion of particles comprising a plurality of a third particle is additionally deposited on the substrate. In one embodiment, the portion of particles is deposited, whereby the plurality of the third particle is dispersed within one or both of the first layer and second layers to form one or more mixed layers of particles. Alternatively, the portion of particles may be deposited, whereby the plurality of the third particle is deposited on the substrate to form a third layer of particles. The plurality of the third particle may be directly deposited on the substrate, or it may be directly deposited on either of the first or second layers.

In one embodiment, the third particle is a CIGSSe particle denoted as Cu(In₁₋ₓ₃Gaₓ₃)(S_{1-y3}Se_{y3})₂ where 0≦x₃≦1 and 0≦y₃≦1. CIGSSe particles for use in the present invention are typically less than about 50 nm in size, preferably less than about 25 nm in size.

In another embodiment, the third particle is a CIGSSe family particle containing at least one element selected from the group consisting of Cu, In, Ga, S, and Se. The CIGSSe nanoparticles when mixed with one or more particles of the CIGSSe family, act as a buffer for the composition control at the nanometer scale for the formation of device quality CIGSSe absorber. In one embodiment, the CIGSSe family particle may be a metal particle containing one or more of Cu, In, and Ga, including alloys and combination thereof. In addition, a CIGSSe family particle may be an oxide or mixed oxide particle containing one or more of Cu, In, or Ga. CIGSSe family particles also chalcogenide compounds containing at least one of Cu, In, or Ga and/or at least one of S, Se, Te, or O.

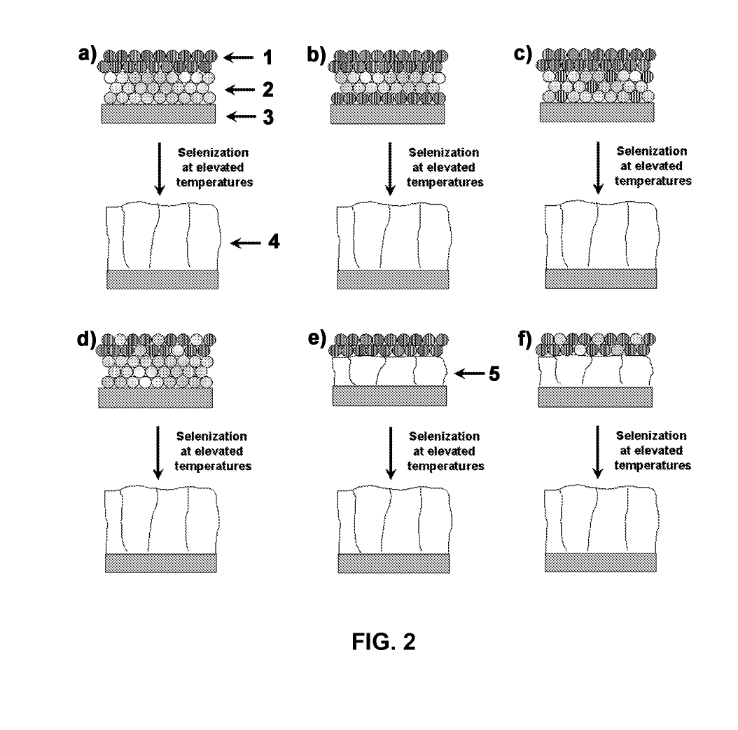

A general method for the fabrication and engineering of composition depth profile in nanoparticle coatings containing CIGSSe nanoparticles is provided, as shown schematically in FIGS. 2a-2d. Multilayer coatings of CIGSSe nanoparticles with different ratios of x and/or y (items 1 and 2 in FIG. 2A) may be coated on a desired substrate of choice (item 3 in FIG. 2A), with at least one of layers having a y less than 1 (i.e. contains a finite amount of sulfur in the CIGSSe nanoparticle), to create the aforementioned band gap profiles.

FIG. 2b shows a profile with three layers in which at least two layers differ from each other in that their CIGSSe nanoparticles have different x and/or y. While two and three layers of CIGSSe nanoparticles are shown in FIGS. 2a and 2b, one can have more than three layers to generate a desired composition depth profile. While in FIGS. 2a and 2b, within any given layer, the CIGSSe nanoparticles can have same or similar values of x and y, it is also possible to have an individual layer comprising CIGSSe nanoparticles of a certain x and y mixed with one or more CIGSSe nanoparticles of different x and/or y. The individual layers may also be comprised of a mixture of CIGSSe nanoparticles with one or more particles of the CIGSSe family of materials as shown in FIGS. 2c and 2d.

A multilayer coating may include two or more layers of CIGSSe nanoparticles with desired x and y applied to a desired substrate. The thickness of a given layer (before annealing) may be several nanometers (a monolayer of CIGSSe nanoparticles) up to several micrometers. Exemplary substrates include glass, metal, plastic, glass coated with metal, plastic coated with metal, etc. The substrate may be flexible or rigid.

Each individual layer in the nanoparticle coating may include CIGSSe nanoparticles with same or similar values of x and y as desired. It is also possible that a given layer may be comprised of CIGSSe nanoparticles of a certain x and y mixed with one or more CIGSSe nanoparticles of different x and/or y. In such a case two or more inks each containing CIGSSe nanoparticles with different values of x and y may be mixed in desired proportions and the resulting ink mixture is used for film coating. Each individual layer in the nanoparticle coating may also include a mixture of CIGSSe nanoparticles with CIGSSe family particles as described above. Where CIGSSe nanoparticles are used in conjunction with other particle sources, the compositions and amounts of the other particles may be weighted to keep the corresponding x and y to at a desired stoichiometry relative to the final corresponding alloy composition.

In one embodiment, a bilayer coating of CIGSSe nanoparticles may be deposited on a substrate, whereby the first layer contains a mixture of Cu(In₁₋ₓGaₓ)S₂ and Cu(In₁₋ₓGaₓ)Se₂ nanoparticles where 0≦x≦1 and the second layer (or top layer, for example) contains another CIGSSe nanoparticle with a varied x and/or y, as desired.

In another embodiment, a bilayer coating of CIGSSe nanoparticles may be deposited on a substrate, whereby the first layer includes a mixture of Cu(In₁₋ₓGaₓ)S₂ and Cu(In₁₋ₓGaₓ)Se₂ nanoparticles where 0≦x≦1 and the second layer (or top layer, for example) includes a mixture two or more CIGSSe nanoparticles with different x and/or y, where at least one of the two or more CIGSSe nanoparticles in the second layer has a y value less than 1.

In yet another embodiment, a multilayer coating of CIGSSe may be deposited on a substrate, whereby the x and y values corresponding to the individual layers are the same or different, provided that at least one of the layers has a y value less than 1, and at least one layer has an x and/or y different from the other layer.

Also, thickness of each individual layer could be several nanometers (a monolayer of CIGSSe nanoparticles) up to several micrometers as desired. Furthermore, the individual layers may be comprised of a mixture of two or more CIGSSe nanoparticles with different x and/or y.

In another embodiment, a multilayer coating may contain two or more layers of particles, each containing at a minimum, Cu, In, and/or Ga, whereby at least one layer contains CIGSSe nanoparticles with y less than 1. In a further embodiment, at least one of the two or more layers includes Se, but no S. Thus, for example, a bilayer coating of a first layer may include Cu(In₁₋ₓGaₓ)Se₂ nanoparticles where 0≦x≦1 and a second layer of Cu(In₁₋ₓGaₓ)S₂ particles where 0≦x≦1.

Annealing

After depositing thin film precursor layers containing CIGSSe nanoparticles on a suitable substrates in accordance with a desired concentration profile, a subsequent treatment under an Se and/or S containing atmosphere at elevated temperature may be used to convert the precursor layers into a CIGSSe absorber film (item 4 in FIG. 2A). Such a treatment enables the reproducible conversion of nanoparticle-based films into densely packed absorber films. Further, through the use of CIGSSe nanoparticles, the film composition can be fixed at the molecular level. It has been determined that by replacing the sulfur with selenium through the selenization process leads to densely packed grains reproducibly. This helps to reduce the porosity in the final absorber layer and provide more stable optoelectronic and electronic properties suitable for further processing into a functional photovoltaic device, or other non-solar related applications.

Annealing may involve heating in an Se containing atmosphere, an S containing atmosphere, or both. An Se containing atmosphere may be provided by a variety of Se sources, including but not limited to H₂Se, Se vapor, Se containing compounds, Se pellets, Se powders, Se particles within the particle-based layers, one or more Se layers on the particle-based layers, a Se coating on at least one of the particles, and combinations thereof. An S containing atmosphere may be provided by a variety of S sources, including but not limited to H₂S, S vapor, S containing compounds, S pellets, S powders, S particles within the particle-based layers, one or more S layers on the particle-based layers, a S coating on at least one of the particles, and combinations thereof.

As described above, one or both of the first and second layers of particles may be annealed individually or in combination to form a CIGSSe thin film having a composition profile along the depth of the film. It should be emphasized that an annealing step may be carried out following the deposition of any individual particle-based layer or it may be carried out following each layer deposition. Thus, in one embodiment, annealing under Se and/or S atmosphere may be performed after the deposition of each individual particle layer in the multilayer coating process. By way of example, in the case of the CuInS₂/CIGS bilayer coating described below, an annealing step under Se and/or S atmosphere may be performed after the CuInS₂ nanoparticle layer and again after the CIGS nanoparticle layer. In addition, individual layers may be annealed under a desired atmosphere of choice, including vacuum, inert, reducing, or oxidizing atmosphere to remove, for example, organic and inorganic additives used during the formulation of the ink solution used for the particle layer. This annealing step may be distinguished from an annealing step performed in the presence of a chalcogen source (including S, Se, or both).

Typically, gas-phase annealing may be performed at a temperature between about 250° C. and about 650° C., and more preferably between about 350° C. and about 550° C. for gas phase reactions. The heat treatment may be performed under a desired atmosphere of choice, including vacuum, inert, reducing, or oxidizing atmosphere to remove, for example, organic and inorganic additives used during the formulation of the ink solution used for the particle layer (this heat treatment step is to be distinguished from the annealing step performed in the presence of chalcogen source).

In an alternate embodiment, annealing under Se and/or S atmosphere can be performed in a liquid phase environment at elevated temperatures with CIGSSe nanoparticles or thin film coatings containing CIGSSe nanoparticles. The liquid phase may include treatment with one or more compatible solvents, such as various alkanes, alkenes, and their derivatives including but not limited to amines, phosphines, phosphine oxides, thiols, carboxylic acids, and phosphonic acids with chalcogen precursors of Se and/or S. The chalcogen precursors to be used in this process may include various elemental chalcogen (such as S, Se), as well as chalcogen compounds and complexes (such as trioctylphosphine selenium complex, sodium selenide, sodium sulfide, selenourea, thiourea, H₂S and H₂Se in solution, various selenides and sulfides). The liquid phase annealing may be performed at temperature ranges of 50° C.-400° C., and more preferable in the range of 150° C.-350° C.

Additional Treatments

The deposition of any or all particle layers may be further accompanied by additional treatments, including chemical treatment, etching, washing, or combination thereof. A washing step may be similarly used after deposition any (or all) particle layer(s) to remove the organic and inorganic additives used during the formulation of the ink. In addition, solutions containing solvents or etchants may be used after deposition any (or all) particle layer(s) for the selective removal of certain additives used when formulating an ink associated therewith. Etchings may be applied to one or more of the first, second layers, and third layers and may be carried out using, for example, an aqueous solution comprising potassium cyanide. An etching may be carried out before or after any given annealing step. The additional treatments may include, for example, the use of a soxhlet extractor, as well as other techniques and apparatuses known to those skilled in the art.

Various wet chemical treatments may be used to remove the organic surfactants and other impurities that may be present in CIGSSe-based nanoparticle based ink solutions, coatings, and/or absorbers. For example, a CIGSSe-based nanoparticle film or absorber may be etched in an aqueous solution containing potassium cyanide (KCN) to remove excess copper selenides. A KCN etching step may be performed prior to and/or following annealing in an Se and/or S containing atmosphere. Alternatively, an aqueous solution containing hydrogen chloride may be used to remove excess metal oxides present in a CIGSSe-based nanoparticle film or absorber prior to and/or following annealing in an Se and/or S containing atmosphere. In another example, a CIGSSe-based nanoparticle ink solution can be washed with various organic or aqueous solutions to remove surfactants and impurities.

### Surface Modification of Pre-existing Absorber Films

In another embodiment, the above-described coating layers, including the first, second, and/or third layers of particles may be deposited for surface composition modification of a pre-existing CIGSSe absorber film. A general method for composition depth profile engineering of a pre-existing dense or porous CIGSSe absorber (item 5 in FIG. 2) with thin film coatings containing CIGSSe nanoparticles is schematically depicted in FIG. 2e. In a typical thin film solar cell, an active and important portion of the absorber layer is near the front (near the Cds/CIGSSe junction in a completed device) where most of the photons are absorbed within few hundreds of nanometers. It is therefore preferable to be able to control the composition near the front of the CIGSSe absorber for optimum performance, e.g. band gap matching with incident light source. Thus, the ability to apply multilayer CIGSSe-based coatings having a desired composition depth profile on pre-existing CIGSSe absorbers can improve the uniformity in the performance of the final devices. The pre-existing absorber film may be porous or non-porous and may be formed using conventional techniques, including but not limited to co-evaporation, sputtering, selenization of various precursor layers, electro-deposition and spray pyrolysis.

In one embodiment, thin film coatings containing CIGSSe nanoparticles are deposited on pre-existing CIGSSe absorbers as single- or multilayer coatings. Thus, in one embodiment, a method for forming a thin film includes providing a substrate having an absorber formed thereon and depositing a layer of particles on the absorber to form a composite precursor film, the layer of particles containing a plurality of a CIGSSe particle having a chemical composition denoted by Cu(In₁₋ₓ₁Gaₓ₁)(S_{1-y1}Se_{y1})₂ where 0≦x₁≦1 and 0≦y₁≦1; and annealing the composite precursor film to form a CIGSSe thin film having a composition profile along the depth of the film.

In another embodiment, a multilayer coating or precursor film is formed on the pre-existing absorber, whereby the subsequent step follow those outlined above. Each individual layer in the nanoparticle coating may include a plurality of a defined CIGSSe nanoparticle having similar or different x and/or y as desired. Each individual layer may also include a mixture of one type of CIGSSe nanoparticle with another type of particle containing one of more of the Cu, In, Ga, Se, and S, (such as a CIGSS family particle; FIG. 2F). For example, each individual layer may include CIGSSe nanoparticles of a certain x and y mixed with one or more CIGSSe nanoparticles of different x and/or y. In another example, each individual layer may include a mixture of CIGSSe nanoparticles with one or more CIGSSe family particles as described above. When mixed with CIGSSe family particles, CIGSSe nanoparticles can act as a buffer for the composition control at the nanometer scale for formation of device quality CIGSSe absorbers. In cases where CIGSSe nanoparticles are used in conjunction with other sources of particles, the amount of the other sources of particles may be weighted to keep the final Cu:In+Ga and In/Ga ratios to within a desired stoichiometry relative to the final corresponding alloy composition.

The sequence of particle depositions on the pre-existing CIGSSe absorber will generally follow the process and steps previously outlined above. Thus, the formation of thin film particle-based layers on a pre-existing CIGSSe absorber entails the deposition of one or more particle layers, including CIGSSe nanoparticles and/or CIGSSe family particles, essentially as described above. The CIGSSe family particles may include metal particles of Cu, In, or Ga, their alloys, and combinations thereof. The CIGSSe family particles may also include oxide or mixed oxide particles of Cu, In, Ga, or Se, or chalcogenide particles of Cu, In, and/or Ga in combination with O, S, Se and/or Te.

As in the above-described method for forming a CIGSSe-based absorber layer, deposited particle layers are subsequently annealed in an Se and/or S containing atmosphere at elevated temperatures for the formation of the corresponding CIGSSe absorber (item 4 in FIG. 2a), as further described above. The source of the Se in the annealing step may be from H₂Se, Se vapor, Se pellets or powder, Se containing compounds (such as sodium selenide, selenourea, diethyl selenium), Se particles mixed within the CIGSSe nanoparticle coating, or alternating layers of Se thin films with CIGSSe nanoparticle layer. The S in the annealing step may be from H₂S, S vapor, S flakes or powder, S containing compounds (such as sodium sulfide, thiourea), S particles mixed within the CIGSSe nanoparticle coating, or alternative layers of S thin film with the CIGSSe nanoparticle layer.

### Particle Compositions and Particle Inks

Each individual layer in the thin film coating may be comprised of CIGSSe nanoparticles having a desired x and/or y. This means that each individual layer in the nanoparticle coating may consist of CIGSSe nanoparticles with all the particles having same or similar values of x and y. Alternatively, each individual layer in the nanoparticle coating may be comprised of CIGSSe nanoparticles of a certain x and y mixed with one or more CIGSSe nanoparticles of different x and/or y. Each individual layer in the nanoparticle coating may also be comprised of a mixture of CIGSSe nanoparticles with one or more particles of the CIGSSe family of materials. By CIGSSe family we mean any suitable particles that contain one or more elements from Cu, In, Ga, S, and Se. The CIGSSe nanoparticles when mixed with one or more particles of the CIGSSe family, act as a buffer for the composition control at the nanometer scale for the formation of device quality CIGSSe absorber. The CIGSSe family of particles may be metal particles of Cu, In, Ga, Se, S and their alloys of the combination thereof. The CIGSSe family of particles may also be oxide or mixed oxide particles of Cu, In, Ga, Se, and S or the combination thereof. Moreover, The CIGSSe family of particles may be chalcogenide particles of Cu, In, and Ga or the combination there of, wherein chalcogenide means compounds of O, S, Se and Te. For the cases where CIGSSe nanoparticles are used in conjunction with other sources of particles, the amount of the other sources of particles are weighted to keep the final Cu/In+Ga and Ga/(In+Ga) ratios to within the desired stoichiometry of the final corresponding alloy composition. Furthermore, the stoichiometry of the CIGSSe nanoparticles may be slightly copper rich or poor, indium rich or poor, gallium rich or poor, and chalcogen rich or poor.

CIGSSe nanoparticles may be synthesized by reacting various metal precursors and chalcogen precursors in a compatible solvent. The metal precursors to be used in such process may include various metal halides (such as copper chlorides and copper iodides), metal chalcogenides (such as copper oxides, copper selenides, and copper sulfides), organic metal salt or complexes (such as copper acetates, copper sulfates, copper nitrates, and copper acetylacetonates, dimetyl copper), elemental metals (such as Cu, In, Ga). The chalcogen precursors to be used in such process may include various elemental chalcogen (such as S, Se), as well as chalcogen compounds and complexes (such as trioctylphosphine selenium complex, sodium selenide, sodium sulfide, selenourea, thiourea, H₂S and H₂Se in solution, various selenides and sulfides). Examples of compatible solvents are various alkanes, alkenes, and their derivatives such as amines, phosphines, phosphine oxides, thiols, carboxylic acids, and phosphonic acids. Herein we give a specific example of a solution synthesis of the CIGSSe nanoparticles to illustrate the embodiments of the present invention. Compositions and methods for synthesizing CIGSSe nanoparticles are described in U.S. Pat. Appl. No. 2010/0003187 to Guo et al., the disclosure of which is incorporated by reference herein.

CIGSSe nanoparticles, including those described in the examples herein, may be synthesized by injection of sulfur and/or selenium dissolved in oleylamine into a hot oleylamine solution containing copper acetylacetonate (CuAcac), indium acetylacetonate (InAcac), and gallium acetylacetonate (GaAcac) as the sources for the metals as previously described (21,22,26). In the case of synthesizing Cu(In₁₋₁Gaₓ)S₂ (CIGS) nanoparticles, only sulfur is used, i.e. precursors containing Se are not introduced. All manipulations were performed using standard air-free techniques utilizing a Schlenk line or glove box. According to the principles of this experimental procedure, 12 ml of oleylamine, 1.5 mmol of CuAcac, and 1.5 mmol combined InAcac and GaAcac were added to a 100 ml three-neck round bottom flask connected to a Schlenk line apparatus. The contents in the flask were heated to 130° C. and purged with argon three times by repeated cycles of vacuuming and back filling with inert gas, and then degassed at ˜130° C. for 30 minutes. Next, the temperature of the reaction mixture was raised to 225° C., and 3 ml of 1 molar solution of sulfur dissolved in oleylamine was rapidly injected into the reaction mixture. The temperature was held at 225° C. for 30 minutes after injection, and the mixture was allowed to cool to 60° C. and a non-polar solvent (e.g. toluene, hexane) was added to disperse the nanoparticles. A miscible anti-solvent (e.g. isopropanol, ethanol) may be added to flocculate the nanoparticles. The nanoparticles were then collected by centrifuging at 12000 RPM for 10 minutes. The dark precipitate may be redispersed in polar solvents or in non-polar solvents, such as hexane and toluene to form a stable ink solution. The ratio of GaAcAc:InaAcAc could be zero or higher as desired to form the corresponding C(In₁₋ₓGaₓ)S nanoparticles. Furthermore, the source of the chalcogen could include S or Se alone, or a mixture of them for the synthesis of corresponding Cu(In₁₋ₓGaₓ)(S_{1-y,}Se)₂ nanoparticles inks, where 0≦y≦1.

Particle Ink Solutions

In preferred embodiments, the particles are deposited onto substrates or other particle layers via one or more particle ink solutions. These ink solutions provide a means for coating CIGSSe nanoparticles or other particles so as to deposit them as a film on a substrate, the film containing one or more layers with varying x and/or y in each layer, depending on the composition of the particles in the ink solution. A particle ink solution may contain a plurality of one particle type or a mixture of different particle types dispersed in one or more polar or non-polar solvents. A given ink solution may include CIGSSe nanoparticles with identical or substantially identical x and/or y values. The ink may also be comprised of CIGSSe nanoparticles of a certain x and y mixed with one or more CIGSSe nanoparticles of a different x and/or y. The ink may also be comprised of a mixture of CIGSSe nanoparticles with one or more CIGSSe particles. The CIGSSe nanoparticles or their mixtures can be suspended in an organic or inorganic solvent with various ligands and surfactant to aid in the suspension of the particles.

Ink solutions containing CIGSSe particles or CIGSSe family particles can be directly applied directly to desired substrates or other particle layers using various methods known to those skilled in the art, such as drop casting, spray coating, inkjet printing, roll coating, knife coating, spin coating, dip coating, web coating, and the like (and combinations thereof). Exemplary substrates include but are not limited to glass, metal, plastic, glass coated with metal, plastic coated with metal, and combinations thereof. The substrate may be configured in various shapes known to those skilled in the art, including as a sheet, such as a foil sheet, cylinder, etc.

A single coating layer of particles may have thickness ranging from between about 2 nm to about 4 μm. The total thickness of the overall single-layer or multi-layer precursor coating(s) may range from about 4 nm to about 8 μm, preferably from about 500 nm to about 4 μm. Following annealing, chalcogen exchange, and/or additional processing steps, the resulting film may be reduced by about 50% in thickness relative to the overall thickness of the precursor coating(s), between about 200 nm and about 2 μm.

The CIGSSe nanoparticles can be dispersed in various polar or non-polar (such as toluene and hexane) solvents to form an ink solution, and used directly to coat desired substrates (such as glass, metals, plastics, glass coated with metal, plastic coated with metal, and etc) to form a nanoparticle thin film comprising of single or multiple layers of various thicknesses. Multilayer coatings of CIGSSe nanoparticle ink solution with varied x and/or y ratios could be used to build desired composition depth profiles. Although the CIGSSe particles can form stable solutions in polar and non-polar solvents, addition of other organic or inorganic materials such as surfactants, stabilizers, leveling agents, and de-oxidation agents may be added to the solution for their respected purposes are within the scope of the present invention. Furthermore, CIGSSe nanoparticle ink solutions based on polar solvents can also be synthesized by the addition of various organic or inorganic materials such as surfactants, stabilizers, solvents, leveling agents, and de-oxidation agents to the solution. Once a stable ink solution is formed, various techniques may be used to coat desired substrates with one or more nanoparticle inks, including drop casting, spray coating, inkjet printing, roll coating, web coating, and others known to those of skill in the art.

### Other Thin Films

The methods and principles described herein may be further applied to other Group nanoparticles, nanoparticle inks, coating methods and thin films therefrom, absorbers therefrom, and photovoltaic devices therefrom. In particular, the present disclosure contemplates an extension of the teachings herein to other Groups

For example, in one embodiment a method for forming a Group IA-IIIA-VIA thin film depositing at least two layers of particles on a substrate, each of the two layers containing a plurality of a Group IA-IIIA-VIA particle including at least one element from Cu, Ag, and Au; at least one element from Al, GA, In, Tl; and at least one element from O, S, Se, and T. Upon coating these layers on a substrate, both of the first and second layers are annealed individually or in combination to form a Group I-III-VI₂ thin film having a composition profile along the depth of the film.

### Group

In a further embodiment, each of the first and second layers includes a plurality of a particle, wherein at least one element in the chemical composition denoted by Cu(In₁₋ₓ₁Gaₓ₁)(S_{1-y1}Se_{y1})₂, is substituted by an element selected from the group consisting of Ag, Au, Al, Tl, O, and Te. In either case, the layers may be annealed in an Se containing atmosphere, and S containing atmosphere, or an atmosphere comprising both Se and S. The additional methods described herein can be equally applied to these other Group IA-IIIA-VIA particle layers.

### Exemplary Thin Film Coatings and Absorbers

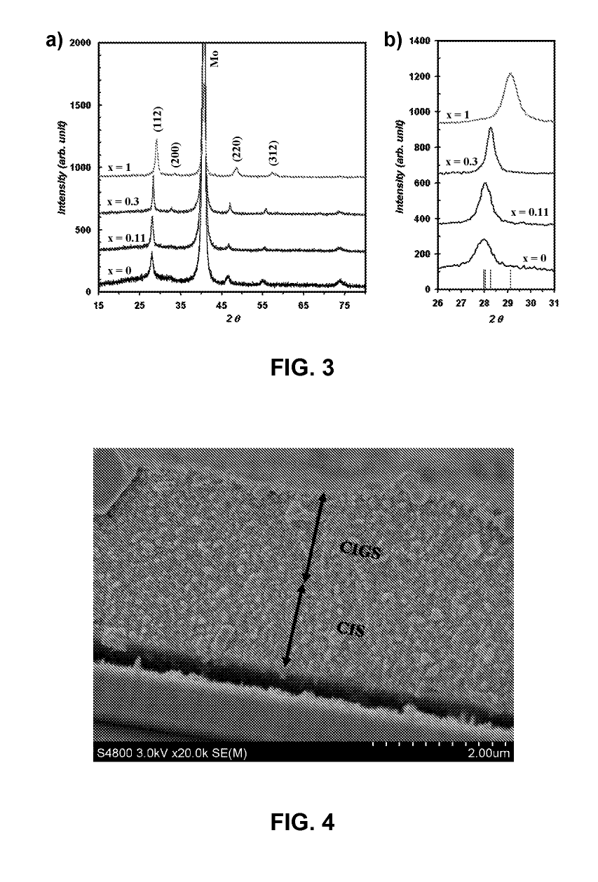

In an exemplary deposition example, drop casting was used to coat substrate. In drop casting, a thin film may be obtained by dropping a desired amount of the ink solution directly on the substrate and allowing the solvent to evaporate away. FIG. 3a shows a PXRD pattern of the CuInS₂ nanoparticles drop-casted on a molybdenum coated substrate. The peaks at 28.04, 32.56, 46.6, and 55.28 can be indexed to the (112), (200), (220) and (312) reflections of the CuInS₂ (x=0) crystal structure. The observed peaks match well with the reference JCPD data. PXRD patterns of Cu(In₁₋ₓGaₓ)S₂ nanoparticles with varied x are also shown in the same plot. The diffraction peaks shift to the right systematically with increasing amount of Ga as expected due to the decrease in the lattice parameters because of smaller atomic size of Ga as compared to In. FIG. 3b shows the expanded view of the (112) peaks of the various CIGS nanoparticles showing the right-shift with increasing Ga content. The crystalline size of the various CIGS nanoparticles estimated from the (112) peaks using the Scherrer equation is ˜15 nm. Nanoparticles of different sizes may be obtained by altering the reaction conditions.

In another example, drop casting was employed to form a bilayer coating of CuInS₂ and Cu(In_{0.79}Ga_{0.21})S₂ nanoparticles on molybdenum coated soda lime glass is given. FIG. 4 is a FE-SEM image of the resulting bilayer coating depicting a ˜1000 nm thick layer of CuInS₂ nanoparticles (bottom layer) and 1000 nm thick layer of Cu(In_{0.79}Ga_{0.21})S₂ nanoparticles (top layer) on molybdenum coated soda lime glass. The image shows that a thin film of densely packed nanoparticles a few micrometers in thickness may be obtained.

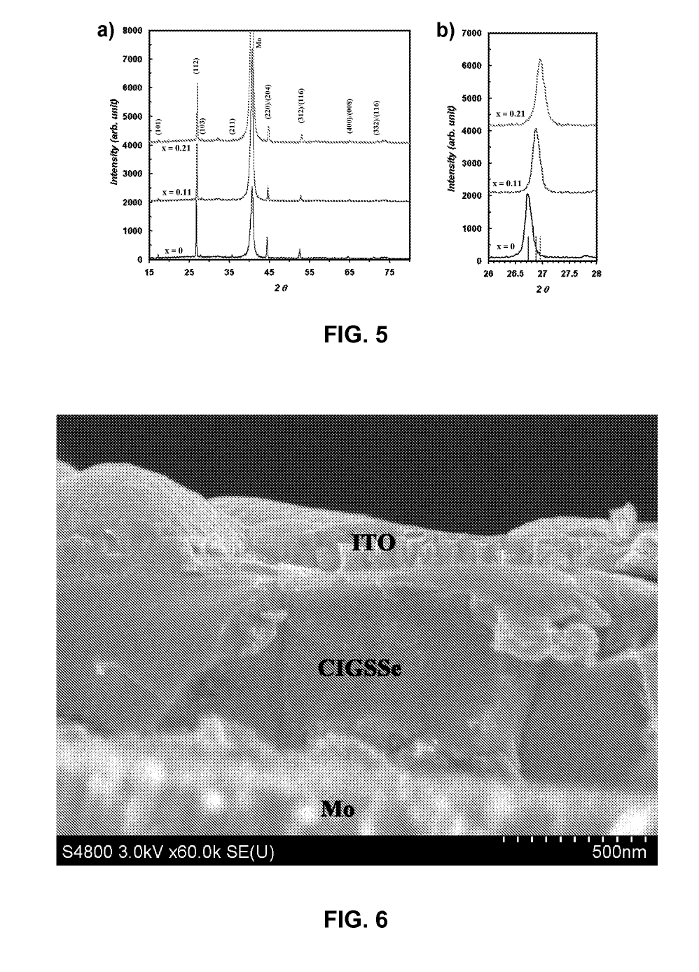

The example in FIG. 5 illustrates the effect of annealing in an Se atmosphere on formation of an absorber film. Prior to selenization, the CIGSSe nanoparticle thin films may be annealed under various atmospheres, such as inert, reducing, and oxidizing atmospheres. One purpose of annealing under various atmospheres is to remove organic surfactants that may be present in the film. The films can then be annealed in a Se containing atmosphere at temperature range from 50° C.-650° C., and more preferably between 350° C.-550° C. for gas phase reaction, for a desired amount time to convert the CIGSSe nanoparticle film into densely packed and large grain CIGSSe absorber. FIG. 5 shows the PXRD pattern of the Cu(In₁₋ₓGaₓ)S₂ absorbers with varied x after annealing under Se containing atmosphere at 500° C. for 20 minutes. The PXRD peaks are indexed accordingly to the chalcopyrite structure of the CIGSSe absorber.

In a further example, FIG. 6 depicts an FE-SEM cross sectional image of a CIGSSe absorber film after annealing of a bi-layer coating consisting of a ˜750 nm CuInS₂ nanoparticle layer (bottom layer) and a ˜500 nm of CIGS nanoparticle layer (top layer) in a Se vapor at 500° C. for 20 minutes is shown in FIG. 6. From the FE-SEM image, it is clear to see that after annealing in a Se vapor, the nanoparticles grow into large and densely packed grains that are on the length-scale of the thickness of the film, a morphological feature of high efficiency CIGSSe absorber-based solar cells. Similar characteristics in recrystallization and grain growth can be seen in final CIGSSe absorbers obtained using different CIGSSe nanoparticle coatings as described above.

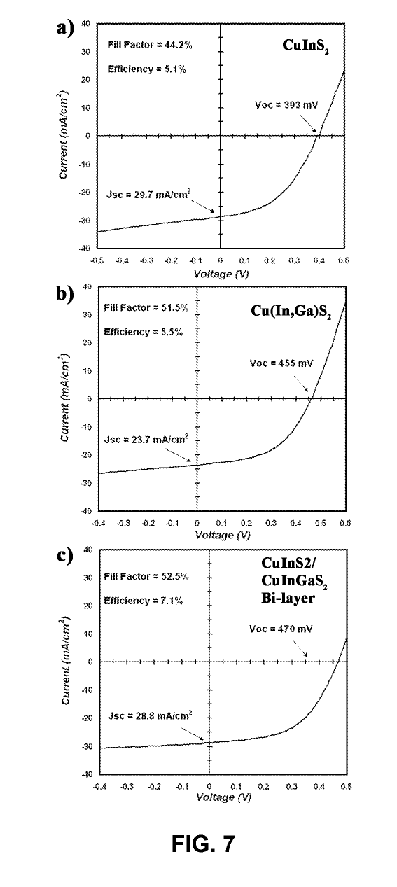

FIG. 7 illustrates the benefits of a band gap engineered absorber layer, including current-voltage (I-V) characteristics of a photovoltaic device fabricated using various absorbers. All of the absorbers were annealed under Se vapor at 500° C. for 20 minutes and then equivalently fabricated to form a photovoltaic device. FIG. 7a shows the I-V characteristic of a photovoltaic device fabricated using an absorber made solely using CuInS₂ nanoparticles with an active area efficiency of 5.1% (Voc=393 mV, Jsc=29.7 mA/cm³, FF=44.2%). In comparison, FIG. 7b shows the I-V characteristic of a photovoltaic device fabricated using an absorber made solely using Cu(In_{0.79}Ga_{0.21})S₂ nanoparticles with an active area efficiency of 5.5% (Voc=450 mV, Jsc=23.7 mA/cm³, FF=51.5%). An increase in Voc is observed with the CIGS nanoparticle based absorber, but Jsc drops significantly. By combining CuInS₂ (bottom layer) and Cu(In_{0.79}Ga_{0.21})S₂ (top layer) in a bi-layer coating, an improved efficiency is observed as shown in FIG. 7c. The photovoltaic device fabricated from the bi-layer coating in FIG. 7c has an active area efficiency of 7.1% (Voc=470 mV, Jsc=28.8 mA/cm³, FF=52.5%).

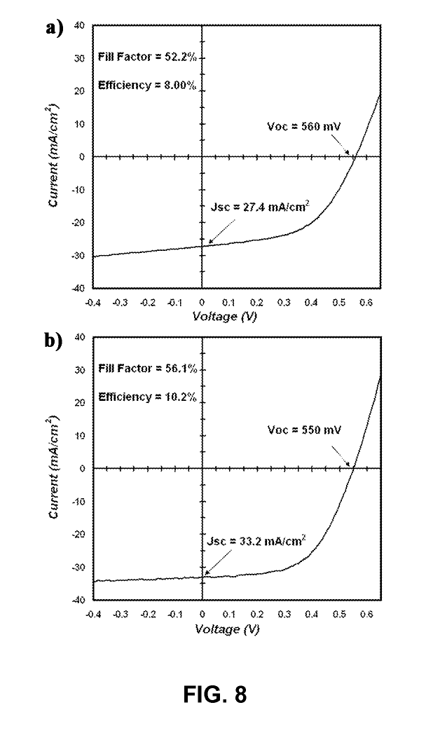

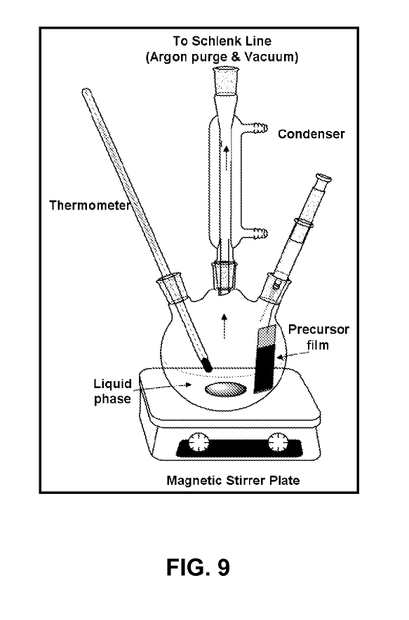

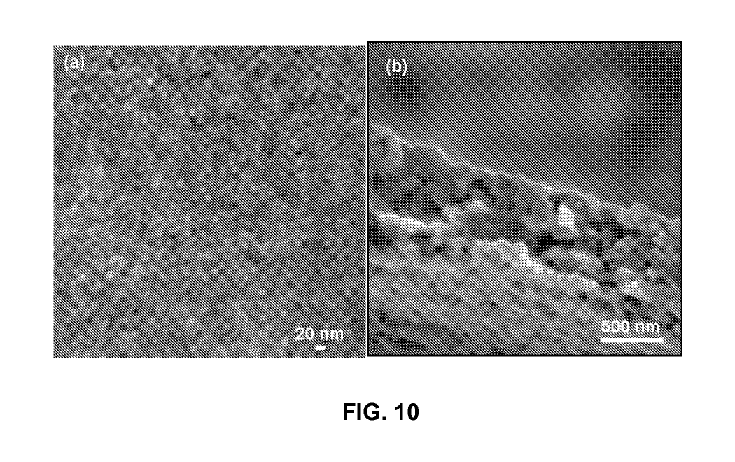

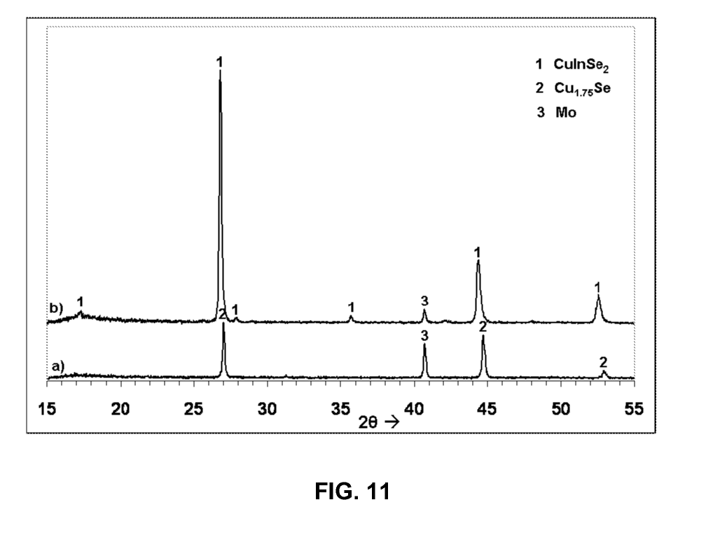

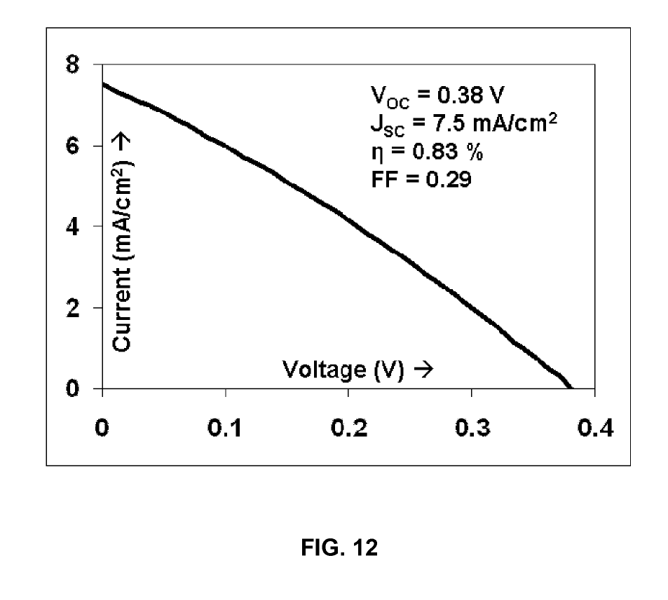

FIG. 8 demonstrate the benefits of KCN etching, showing the I-V characteristics of photovoltaic devices fabricated with KCN etching of CIGSSe nanoparticle layer pre and/or post annealing under Se and/or S containing atmosphere were determined. The photovoltaic devices were equivalently fabricated with the exception of differences. FIG. 8a shows an I-V characteristic of a photovoltaic device fabricated with a CIGSSe absorber with KCN etching (0.5 molar, 5 minutes) post annealing under Se vapor. The devices shows an active area efficiency of 8.00% (Voc=560 mV, Jsc=27.4 mA/cm³, FF=52.2%). In contrast, FIG. 8B shows an I-V characteristic of a photovoltaic device fabricated with a CIGSSe absorber with KCN etching pre (0.5 molar 5 minutes) and post (0.5 molar, 5 minutes) annealing under Se vapor. This device shows an active area efficiency of 10.2% (Voc=550 mV, Jsc=33.2 mA/cm³, FF=56.1%). The benefits of KCN etching are evident from the increased active area efficiency observed in the device exemplified in FIG. 8b.

The compositions and methods described herein should not be construed as limited to CIGSSe nanoparticles or CIGSSe family particles. Similar compositions, methods, and techniques for fabrication of nanoparticle inks, coatings, and absorbers are applicable to and may be extended to other semiconductors of the I-III-VI₂ family known to those skilled in the art, including semiconductors employing various alloys of aluminum (Al), copper (Cu), gallium (Ga), indium (In), iron (Fe), selenium (Se), silver (Ag), sulfur (S), tellurium (Te), and combinations thereof.

### Multinary Metal Chalcogenide Thin Film Formation by Solution Phase Chalcogenization

In another aspect, the present disclosure provides deposition methods for forming multinary metal chalcogenide semiconductor layers directly on a substrate from a solution of precursors. In this case, formation of the semiconductor takes place by the reaction of the precursors on the surface of the substrate followed by the growth of the semiconductor layer on the initially formed nuclei. This process advantageously provides for the simultaneous formation and growth of the semiconductor leading to larger polycrystalline grains, hence better performance and reduced costs associated with device-quality semiconductor films fabricated using this process.

In one embodiment, a method for forming a multinary metal chalcogenide thin film includes depositing a plurality of metal chalcogenide particles onto a substrate to form a precursor film. A species containing a metal, chalcogen, or combination thereof is dissolved in a solution containing one or more solvents to form a liquid chalcogen medium. The precursor film is contacted with the liquid chalcogen medium at a temperature of at least 50° C. to form a multinary metal chalcogenide thin film. Thus, when the precursor film on the substrate is brought in contact with either a chalcogen and/or a metal-containing species dissolved in a liquid phase medium, a thin film of a multinary metal chalcogenide compound may form from the metals present in the precursor film and the liquid phase medium. The liquid phase medium includes one or more solvents, which are typically long-chain hydrocarbon compounds with the number of the carbons in the chain typically in the range of 5 to 20. The solvents may have one or more of the following functional groups, including amines, carboxylic acids, thiols, phosphines, phosphine-oxides, alkanes and alkenes. Typical solvents include oleylamine, hexadecylamine, octadecane, 1-octadecene, dodecanethiol etc.

A preferred liquid phase medium may include a chalcogen in elemental form (such as S, Se), in complex form (such as trioctylphosphine selenium complex), or in the compound form (sodium selenide, sodium sulfide, selenourea, thiourea, H₂S and H₂Se in solution, various sulfides and selenides); or of a metal-containing species which could either be the metal itself or a chloride, iodide, oxide, selenide, sulfide, nitrate, sulfate, acetate, acetylacetonate, dimethyl salt of the metal or both.

The method may include first depositing a precursor film containing one or more elements or compounds on a substrate. The precursor film may include a metal, a multinary metal-chalcogenide, or combination thereof, where the number of elements in the multinary compound may vary between 1 and 5 (or more). The elements or compounds present in a precursor film for the deposition of the multinary metal chalcogenide may include one or more elements selected from groups IB, IIIA, and VIA. These elements may be present as elements and/or as binary and/or ternary or quaternary compounds with chalcogens of group VIA.

Thus, by way of example, when the goal is to form CuIn₁₋ₓGaₓ(S_{y}Se_{1-y})₂ metal chalcogenide film (with 0≦x≦1 and 0≦y≦1), the precursor film may include (1) Cu and/or In and/or Ga as metals or alloys; (2) binary metal compounds, including binary metal compounds of Cu, In, Ga such as Cu_{z}Se, Cu₂S, Cu_{z}O (where 1≦z≦2), InₜSe, InₜS, InₜO, GaₜSe, GaₜS and GaₜO (where 0.5≦t≦1) etc.; (3) ternary compounds of Cu and/or In and/or Ga such as CuInS₂, CuGaS₂, CuInSe₂ etc.; or (4) quaternary compounds of Cu, In and Ga such as CuIn₁₋ₓGaₓ(S_{y}Se_{1-y})₂ where, 0≦x≦1 a 0≦y≦1.

A precursor film may contain only one of the four categories listed above, or it may contain two or more of the listed categories. Thus, when depositing a CuIn₁₋ₓGaₓ(S_{y}Se_{1-y})₂ film, it is possible to have a precursor film that contains Cu metal particles film on a substrate (category 1), along with binary, ternary, and/or quaternary compounds in categories (2)-(4).

As described above, the metal chalcogenide particles may include one or more elements from each of Groups IB, IIIA, and VIA of the Periodic Table (CAS Version, CRC Handbook of Chemistry and Physics). Chalcogen elements in group IB include Cu, Ag and Au; elements in group IIIA include B, Al, Ga, In and Tl; elements in group VIA include O, S, Se, Te. Among the metal chalcogenides in the present invention, one can have one or more elements from the same group. Thus, when one uses Cu from group IB, Ga and In from group IIIA, and S and Se from group VIA, the metal chalcogenides of interest will have the general formula of CuIn₁₋ₓGaₓ(S_{y}Se_{1-y})₂ where 0≦x≦1 and 0≦y≦1. While CuIn₁₋ₓGaₓ(S_{y}Se_{1-y})₂ refers to a stoichiometric composition, one can have Cu-rich or Cu-poor and similarly chalcogen-rich or chalcogen-poor metal chalcogenides.

Elements from Groups IB, IIIA, and VIA may be present as elements, binary compounds, ternary compounds, quaternary compound, or combinations thereof. The one or more elements may include Cu, In, Ga, or a combination thereof. The binary compound may provide at least some of the one or more elements. Exemplary binary compounds include Cu_{z}Se, Cu_{z}S, Cu_{z}O, In_{z}Se, In_{z}S, In_{z}O, Ga_{z}Se, Ga_{z}S, Ga_{z}O, and combinations thereof, where 1≦z≦2. Additional binary compound examples, include InₜSe, InₜS, InₜO, GaₜSe, GaₜS, GaₜO, and combinations thereof, where 0.5≦t≦1. Similarly, ternary or quaternary compounds may also provide at least some of the one or more elements. Exemplary ternary compounds include CuInS₂, CuGaS₂, CuIn Se₂, and combinations thereof.

In another embodiment, the precursor film may contain (a) metal particles (as described in category (i) above) and/or (b) binary metal chalcogenide denoted by the formula Mₘ-(VIA)ₓ, where the binary metal chalcogenide includes at least one element from Group VIA of the Periodic Table, where M is a metal element, where 0<m≦2, and where 0<x≦2. Exemplary metal elements include Fe, Ni, Bi, Pb, Cd, Ag, Cu, Zn, W, In, and Bi. Exemplary, non-limiting binary chalcogenides in accordance with formula Mₘ-(VIA)ₓ include FeS₂, NiS, Bi₂S₃, PbS, CdS, and Cu₂S. A precursor film may contain only one of both of the two categories (a)-(b) listed above. Thus it is possible to have a precursor film that contains Fe metal particles film on a substrate (category i)) along with a binary compound such as FeₘS etc. in order to deposit a FeₘSe film.

In a preferred embodiment, the metal chalcogenide particles are deposited on the substrate as a plurality of nanoparticles synthesized by solution phase chemistry. Exemplary solution-based deposition techniques include drop casting, spray coating, inkjet printing, roll coating, knife coating, spin coating, dip coating, web coating, and combinations thereof.

The liquid chalcogen medium may include an elemental chalcogen source, a chalcogen complex, a non-metal chalcogen compound, a metal chalcogen compound, a metal chalcogen salt, a metal, or combination thereof. Exemplary metal salts include chlorides, iodides, oxides, selenides, sulfides, nitrates, sulfates, acetates, acetylacetonatse, dimethyl salts thereof, and combination thereof. Solvents for use in the liquid chalcogen may include a hydrocarbon having between about 5 to about 20 carbons and at least one functional group selected from the group consisting of amines, carboxylic acids, thiols, phosphines, phosphine-oxides, alkanes, alkenes, and combinations thereof.

The precursor film may be contacted with the liquid chalcogen medium at a temperature between about 150° C. and about 350° C. In addition, the precursor film may be contacted with the liquid chalcogen medium for a desired period of time, preferably between about 30 minutes and about 120 minutes.

In one embodiment, the metal chalcogenide particles and the liquid chalcogen medium are formulated so that chalcogen in the liquid chalcogen medium is incorporated into the precursor film, resulting in a multinary chalcogenide thin film containing chalcogen from the liquid chalcogen medium. In another embodiment, the metal chalcogenide particles and the liquid chalcogen medium are formulated so that chalcogens in the precursor film are exchanged with chalcogens in the liquid chalcogen medium. In a further embodiment, the precursor film includes a multinary metal chalcogenide, where contact with chalcogen in the liquid chalcogen medium results in sintering of a nanocrytalline or polycrystalline precursor film into larger polycrystalline grain sizes. The above-described method may further include an annealing step to improve the crystallinity and adhesion of the precursor film.

### Photovoltaic Applications of Thin Films

Thin films synthesized in accordance with the above-described methods have suitable optical properties, and can be used as the light absorber in a photovoltaic device. The types of photovoltaic devices include but not limited to all-inorganic solar cells (preferably thin film solar cells), organic-inorganic hybrid solar cells, and photoelectrochemical solar cells as known by those of skill in the art.

Following annealing in a Se and/or S containing atmosphere, an absorber will have electronic and optical properties suitable for further fabrication to form a functional photovoltaic device. When fabricating a photovoltaic device, device fabrication steps may include a variety of different steps. When forming a photovoltaic cell, a thin film according to the present disclosure is deposited on a substrate. The substrate may be flexible or rigid. Flexible substrates include but are not limited to high thermal stability polymers, such as polyimides, polymer composites, metal foils, and the like. Rigid substrates include but are not limited to sodalime glass, borosilicate glass, fused silica, quartz, thick metal foils, steel, carbon fiber composites, and the like. The substrate may first be coated with an opaque or transparent conducting layer to form a conducting substrate. Exemplary conducting layers include metals, including but not limited to molybdenum, aluminum, gold silver, copper, tin, zinc, indium, gallium, tungsten, nickel, and cobalt, conducting polymers; carbon nanotube composites, graphene, and conducting oxides, including but not limited to tin doped indium oxide, fluorine doped tin oxide, and aluminum doped zinc oxide. Alternatively, the thin film may be deposited on a conductive substrate where substrate may be made of a conductive material.

The conducting substrate may be coated with any of the above-described nanoparticle-based coating layers, which may be further subjected to additional chemical or thermal treatments as described above. A second semiconductor layer may then be deposited to form a semiconductor junction. The second semiconductor layer may be deposited by a variety of methods including vapor deposition, spray pyrolysis, chemical bath deposition, electrodeposition, nanoparticle ink coating, or other solution phase deposition methods. The second semiconductor layer may include but is not limited to CdO, CdS, CdSe, CdTe, ZnO, ZnS, ZnSe, ZnTe, SnO, SnO₂, SnS, Sn₂S, SnSe, SnSe₂, SnTe, SnTe₂, CuO, Cu₂O, CuS, Cu₂S, CuSe, Cu₂Se, CuTe, Cu₂Te, CZTSSe, CIGSSe, and combinations thereof. The second semiconductor layer may also be deposited before depositing the particle-based coating layers to from an absorber. Upon deposition of the particle-based layers and the second semiconductor layer, an opaque or transparent conducting layer may be deposited. Alternatively, the second semiconductor layer may be omitted entirely to form a Schottky junction photovoltaic device containing a thin film according to the present disclosure.

In one embodiment, a method for fabricating a photovoltaic cell includes providing a conductive substrate; forming a thin film according to any of the above-described embodiments on the substrate, and forming a top electrode on the substrate, whereby at least one of the conductive substrate and top electrode is transparent. A second semiconductor layer may be further deposited on the substrate.

In another embodiment, a method for fabricating a photovoltaic device includes providing a conductive substrate; forming a CIGSSe thin film on the substrate according to any of the embodiments described herein; forming a top conducting electrode on the CIGSSe thin film; and forming printed or vacuum-deposited busbars on the top conducting electrode.

In a further example, a cadmium sulfide layer (˜50 nm) may be formed by chemical bath deposition on top of an CIGSSe absorber layer, followed by sputtering of intrinsic zinc oxide (˜50 nm) and tin doped indium oxide layers (˜250 nm) and metal grids for top contacts.

In an a further example, one could form a layer of CuInSₑ₂ as disclosed herein on top of a metal contact, such as Mo either in the form of metal foil or supported on a rigid or flexible substrate (e.g. glass, plastic or other metallic substrates such as steel). The metallic substrates can be coated with an ultra-thin layer (less than 50 nm and preferably less than 10 nm) of a high band gap material such as Al₂O₃, TiO₂ etc. The CuInSe₂ layer could then be covered with a buffer layer, which can be metal chalcogenide such as CdS or ZnSe. This buffer layer can be deposited in the same fashion as the CuInSe₂ layer using any of the methods of the present disclosure or it could be deposited more conventionally (e.g. by chemical bath deposition). This buffer layer could then be covered by a transparent conducting oxide such as doped TiO₂, indium tin oxide or fluorine-doped tin oxide. Metal contact deposition such as Ni/AI on top of the TCO would complete the photovoltaic cell.

The examples of photovoltaic devices presented herein are useful in highlighting the benefits of the present invention. However, applications of the technology described herein should not be construed as being limited to photovoltaic devices, but may be used in other non-solar related electronic devices.

### EXAMPLES

### Example 1

Cu_{z}Se (1≦z≦2) nanocrystals were synthesized in the solution phase from CuCl and elemental Se precursors using oleylamine as a solvent. 7.5 ml of oleylamine was added to a 25 ml three-neck round bottom flask (FIG. 1) connected to a Schlenk line apparatus, degassed at around 130° C. and purged with Argon gas alternatively and heated to a temperature preferably between 200° C. and 300° C. In this particular example 0.5 ml of 1 molar Se in oleylamine was added to the reaction mixture at 250° C. and left for heating for 15 minutes, after which 2 ml of 0.25 molar CuCl-oleylamine was added. The contents of the reactor were kept at 250° C. for 30 minutes after which it was cooled down to room temperature.

A ‘nanoink’ of Cu_{z}Se was prepared by dispersing the 10-15 nm sized Cu_{z}Se nanocrystals (FIG. 2(a)) in toluene after getting rid of the excess oleylamine through centrifugation. A 1.5 μm thick layer of Cu_{z}Se nanocrystals was drop-casted on to a 2.5 cm×1 cm×0.025 cm sized molybdenum foil. After letting the excess toluene evaporate, the precursor film of Cu_{z}Se was annealed in a furnace tube under argon flow at 300° C. for 60 minutes. It is observed that this annealing step improved the adhesion and crystallinity of the Cu_{z}Se layer as seen in the powder x-ray diffraction patterns (FIG. 3(a)).

A three neck round bottom flask connected to a Schlenk line (FIG. 1) consisting of 12.5 mg of InCl₃ dissolved in 10 ml of oleylamine was taken. The substrate with the precursor film was held by a metal coil that was needled through two punched holes in the substrate. This precursor film was then placed inside the flask but not dipped in the liquid phase at the start of the experiment. A stirring speed of 100 rpm. was employed for these experiments. The contents of the flask were purged with argon gas and degassed alternatively for three cycles to minimize the presence of oxygen and water vapor in the flask. The contents of the flask were then heated to a temperature of 280° C., after which the precursor film (FIG. 2(a)) was dipped into the liquid phase. The reaction between Cu_{z}Se and InCl₃ was carried out for 30 minutes. At the end of the desired time of reaction, the product film was pulled out of the liquid phase, and was allowed to cool in the vapor phase. Meanwhile, the liquid phase was also cooled back to room temperature. The product multinary metal chalcogenide film containing CuInSe₂ was rinsed with toluene to remove excess oleylamine on the surface and left to dry at room temperature. The cross-sectional view of the product film is shown in FIG. 2(b) which clearly shows grain-growth as compared to the precursor film. Powder x-ray diffraction patterns (FIG. 3(b)) confirm the formation of the chalcopyrite crystal structure of CuInSe₂ as seen by the presence of primary as well as secondary peaks.

The resulting films were etched in a 0.5 molar aqueous solution of KCN to get rid of excess Cu_{z}Se left in the layered structure. The resulting films were etched in a Br₂/methanol solution to decrease the surface roughness of the films. The p-type CuInSe₂ layer was then covered with a n-type CdS buffer layer which was deposited by chemical bath deposition, followed by RF sputtering of 50 nm intrinsic ZnO and 300 nm of ITO layers. The corresponding I-V characteristic of the solar cell is shown in FIG. 4. The devices had an efficiency and open-circuit voltage of 0.83% and 380 mV respectively.

### Example 2

Copper nanocrystals were synthesized in the solution phase from CuCl using oleylamine as the solvent. For the synthesis of Cu nanocrystals, a three-necked flask consisting of 7.5 ml of oleylamine was taken at room temperature, and heated to a temperature anywhere between 100° C. and 350° C., preferably between 200° C. and 300° C. 2 ml of 0.25 molar CuCl-oleylamine was added to the reaction mixture at 280° C. The contents of the reactor were kept at 280° C. for 30 minutes, after which it was cooled down to room temperature.

Indium nanocrystals were synthesized in the solution phase from InCl₂ using oleylamine as the solvent. For the synthesis of In nanocrystals, a three-necked flask consisting of 7.5 ml of oleylamine was taken at room temperature, and heated to a temperature anywhere between 100° C. and 350° C., preferably between 100° C. and 200° C. 2 ml of 0.25 molar InCl₂-oleylamine was added to the reaction mixture at 110° C. The contents of the reactor were kept at 110° C. for 30 minutes after which it was cooled down to room temperature.

A copper and indium ‘nanoink’ (1:1 Cu:In molar ratio) was prepared by dispersing the nanoparticles in toluene after getting rid of the excess oleylamine through centrifugation. A 1 μm thick layer of Cu and In nanocrystals was drop-casted on to a 2.5 cm×1 cm×0.025 cm sized molybdenum foil. After letting the excess toluene evaporate, this precursor film of Cu and In nanoparticles was annealed in a furnace tube under argon flow at 300° C. for 60 minutes. It is observed that this annealing step improved the adhesion and crystallinity of the bimetallic layer.

A three-necked flask (FIG. 1) consisting of 10 ml of oleylamine was taken. The substrate with the precursor film was held by a metal coil that was needled through two punched holes in the substrate. This precursor film was then placed inside the flask but not dipped in the liquid phase at the start of the experiment. The contents of the flask were purged with argon gas and degassed alternatively for three cycles to minimize the presence of oxygen and water vapor in the flask. The contents of the flask were then heated to a temperature of 280° C., after which 4.2 mg of elemental Selenium (suspended in 1 ml of oleylamine) was injected in to the reactor flask. After waiting for 15 minutes at 280° C. the precursor film was dipped into the liquid phase, and the reaction between the metals and selenium was allowed to continue for 60 minutes. At the end of the desired time of reaction, the product film was pulled out of the liquid phase, and was allowed to cool in the vapor phase. Meanwhile, the liquid phase was also cooled back to room temperature. The product multinary metal chalcogenide film containing CuInSe₂ (as verified from powder x-ray diffraction measurements) was rinsed with toluene to remove excess oleylamine on the surface and left to dry at room temperature.

In some cases, the resulting multinary metal chalcogenide films were dipped into a liquid phase medium containing InCl₃ in oleylamine at temperatures typically between 200° C. and 300° C. for a time period typically between 15 and 60 minutes. In some other cases, the resulting films were again dipped into a liquid phase medium containing selenium in oleylamine at temperatures typically between 200° C. and 300° C. for a time period typically between 15 and 60 minutes. In some other cases, the resulting films were alternatively dipped into separate liquid phase mediums containing selenium and InCl₃ iteratively to get rid of the excess Cu_{z}Se. In some other cases, the resulting films were post-processed by annealing at about 200° C. in air for about 5 to 30 minutes. In some other cases, the resulting films were etched in a 0.5 molar aqueous solution of KCN to get rid of excess Cu_{z}Se left in the layered structure. In some other cases, the resulting films were etched in a Br₂/methanol solution to decrease the surface roughness of the films.

Although the description herein contains many specific details for the purpose of illustration, those of ordinary skill in the art will appreciate that many variations and alterations to the following details are within the scope of the disclosure and aspects of the invention. Further, it should be noted that any of the chemical elements, compounds, particles, nanoparticles, inks, coating treatments and methodologies described herein, and in related U.S. patent application Ser. Nos. 12/301,317, filed Nov. 18, 2008, and 61/146,084, filed Jan. 21, 2009, both incorporated by reference in their entirety herein, may be utilized in any of the processes and composition described herein, even where they are not expressly identified or directed to a particular use, so long as the relied upon compositions and methods are applicable to the teachings and practice of the invention (or inventions) described herein. Moreover, the exemplary embodiments of the invention described below are set forth without any loss of generality to, and without imposing limitations upon, the claimed invention.

### REFERENCES

1. U.S. Pat. No. 5,078,804.

2. Siebentritt S. 2002. Wide gap chalcopyrites: material properties and solar cells. Thin Solid Films:1-8.

3. Stanbery B J. 2002. Copper indium selenides and related materials for photovoltaic devices. Critical Reviews in Solid State and Materials Sciences 27:73-117.

4. Ramanathan K, Contreras M A, Perkins C L, Asher S, Hasoon F S, Keane J, Young D, Romero Y, Metzger W, Noufi R, Ward J, Duda A. 2003. Properties of 19.2% efficiency ZnO/CdS/CuInGaSe2 thin-film solar cells. Progress in Photovoltaics 11:225-30.

5. U.S. Pat. No. 5,730,852.

6. Birkmire R W, Schultz J M, Marudachalam Y, Hichri H. 1997. U.S. Pat. No. 5,674,555.

7. U.S. Pat. No. 6,323,417.

8. U.S. Pat. No. 5,501,786.

9. U.S. Pat. No. 5,489,372.

10. Hollingsworth J A, Banger K K, Jin M H C, Harris J D, Cowen J E, Bohannan E W, Switzer J A, Buhro W, Hepp A F. 2003. Single source precursors for fabrication of I-III-VI2 thin-film solar cells via spray CVD. Thin Solid Films 431:63-7.

11. U.S. Pat. No. 5,445,847.

12. Eberspacher, C., et al., Thin-film CIS alloy PV materials fabricated using non-vacuum, particles-based techniques. Thin Solid Films, 2001. 387(1-2): p. 18-22.

13. U.S. Pat. No. 6,127,202.

14. Kaelin, Y., et al., CIS and CIGS layers from selenized nanoparticle precursors. Thin Solid Films, 2003. 431: p. 58-62.

15. Alberts, V., J. Titus, and R. W. Birkmire, Material and device properties of single-phase Cu(In,Ga)(Se,S)(2) alloys prepared by selenization/sulfurization of metallic alloys. Thin Solid Films, 2004. 451-52: p. 207-211.

16. Kemell, Y., Y. Ritala, and Y. Leskela, Thin film deposition methods for CuInSe(2) solar cells. Critical Reviews in Solid State and Materials Sciences, 2005. 30(1): p. 1-31.

17. Arici, E., et al., Morphology effects in nanocrystalline CuInSe2-conjugated polymer hybrid systems. Applied Physics a-Materials Science & Processing, 2004. 79(1): p. 59-64.

18. Huynh, W. U., J. J. Dittmer, and A. P. Alivisatos, Hybrid nanorod-polymer solar cells. Science, 2002. 295(5564): p. 2425-2427.

19. Gur, I., Air-stable all-inorganic nanocrystal solar cells processed from solution (21 Oct, pg 462, 2005). Science, 2005. 310(5754): p. 1618-1618.

20. U.S. Pat. No. 7,306,823 B2.

21. International Publication No. WO 2008/021604, published Feb. 21, 2008.

22. Guo Q, Kim S J, Kar Y, Shafarman W N, Birkmire R W, Stach E A, Agrawal R, Hillhouse H W. 2008. Development of CuInSe2 nanocrystal and nanoring inks for low-cost solar cells. Nano Letters 8:2982-7.

23. Jensen C L, Tarrant D E, Ermer J H, Pollock G A. 1993. The role of gallium in CuInSe2 solar cells fabricated by a two-stage method. Photovoltaic Specialists Conference, 1993:557-80.

24. Adurodija F O, Song J, Kim S D, Kim S K, Yoon K H. 1998. Characterization of CuInS2 thin films grown by close-spaced vapor sulfurization of co-sputtered Cu—In alloy precursors. Japanese Journal of Applied Physics Part 1-Regular Papers Short Notes & Review Papers 37:4248-53.

25. Alberts V, Titus J, Birkmire R W. 2004. Material and device properties of single-phase Cu(In,Ga)(Se,S)(2) alloys prepared by selenization/sulfurization of metallic alloys. Thin Solid Films 451:207-11.

26. U.S. Patent Application Publication No. US 2010/0003187, published Jan. 7, 2010.

1-65. (canceled)

66. A method for forming a CIGSSe thin film, the method comprising:
depositing a first layer of particles on a substrate, the first layer comprising a plurality of a CIGSSe particle having a chemical composition denoted by Cu(In₁₋ₓ₁Gaₓ₁)(S_{1-y1}Se_{y1})₂ where 0≦x₁≦1 and 0≦y₁≦1;
depositing a second layer of particles on a substrate, the second layer comprising a plurality of a CIGSSe particle having a chemical composition denoted by Cu(In₁₋ₓ₂Gaₓ₂)(S_{1-y2}Se_{y2})₂ where 0≦x₂≦1 and 0≦y₂≦1; a plurality of a CIGSSe family particle containing at least one element from the group consisting of Cu, In, Ga, S, and Se; or both;
annealing individually or in combination one or both of, the first and second layers of particles to form a CIGSSe thin film having a composition profile along the depth of the film.

67. The method of claim 66, where the second layer of particles comprises a plurality of a CIGSSe particle having a chemical composition denoted by Cu(In₁₋ₓ₂Gaₓ₂)(S_{1-y2 Se}_{y2})2 where 0≦x₂≦1 and 0≦y₂≦1.

68. The method of claim 66, where x₁=x₂.

69. The method of claim 66, where y₁=y₂.

70. The method of claim 66, where x₁=x₂ and y₁=y₂.

71. The method claim 66, where at least one of x₁ and x₂ is equal to 0.

72. The method of claim 66, where at least one of y₁ and y₂ is equal to 0.

73. The method of claim 66, where at least one of y₁ and y₂ is less than 1.

74. The method of claim 66, where 0<y₁<1 or 0<y₂<1.

75. The method of claim 66, further comprising depositing a portion of particles comprising a plurality of a third particle on the substrate to form a third layer of particles.

76. The method of claim 75, where the particles of the first, second, and third layers are about 50 nm in size or less.

77. The method of claim 66, whereupon the deposition of any particle layer on the substrate, the particle layer is subjected to chemical treatment, heat treatment, etching, washing, or combination thereof.

78. The method of claim 66, where an annealing step is carried out after deposition of each particle-based layer, and where the annealing step comprises heating in one of an inert, reducing, and oxidizing atmosphere.

79. The method of claim 66, further comprising forming a CIGSSe absorber film on the substrate prior to forming the first layer.

80. The method of claim 66, further comprising etching one or more of the first, second, and third layers.
